(19) United States
(12) Patent Application Publication
(10) Pub. No.: US 2024/0331773 A1
(43) Pub. Date: Oct. 3, 2024

(54) MEMORY CIRCUIT AND IC CHIP

(71) Applicant: ROHM CO., LTD., Kyoto (JP)

(72) Inventors: Takashige HAMA, Kyoto (JP); Kazuhisa UKAI, Kyoto (JP)

(21) Appl. No.: 18/741,064

(22) Filed: Jun. 12, 2024

Related U.S. Application Data
(63) Continuation of application No. PCT/JP2022/042224, filed on Nov. 14, 2022.

(30) Foreign Application Priority Data
Dec. 14, 2021 (JP) 2021-202149

(51) Int. Cl. G11C 16/04; G11C 16/28; H10B 41/35

(52) U.S. Cl. CPC G11C 16/0483; G11C 16/28; H10B 41/35

(57) ABSTRACT

Provided is a memory circuit that is provided to an IC chip, the memory circuit including: a complementary cell which includes a first memory cell that includes a first memory transistor, and a second memory cell that includes a second memory transistor; a reference cell which includes a reference transistor; a first terminal which is connectable to a gate of the first memory transistor and a gate of the second memory transistor, and to which a first power-supply voltage can be applied; a second terminal which is connectable to a gate of the reference transistor, and to which a second power-supply voltage can be applied; and a detection unit which detects a magnitude relationship between current that flows through the first memory cell or the second memory cell, and current that flows through the reference cell.

### CROSS-REFERENCE TO RELATED APPLICATIONS

This nonprovisional application is a continuation application of International Patent Application No. PCT/JP2022/042224 filed on Nov. 14, 2022, which claims priority to Japanese Patent Application No. 2021-202149 filed on Dec. 14, 2021, the entire contents of which are hereby incorporated by reference.

### TECHNICAL FIELD

The present disclosure relates to a memory circuit.

### BACKGROUND ART

Hitherto, semiconductor memory apparatuses including memory cells have been known. The memory cells include memory transistors. In some of the memory transistors each including a control gate and a floating gate, erasing and writing (programming) are performed by application of high voltage to an oxide film adjacent to the floating gate to cause electrons to be injected into and extracted from the floating gate (refer, for example, to Patent Literature 1).

### CITATION LIST

### Patent Literature

Patent Document 1: Japanese Patent Application Laid-open No. 2017-174485

### BRIEF DESCRIPTION OF DRAWINGS

FIG. 1 is a diagram showing a configuration of a memory cell.

FIG. 2 is a view illustrating a vertical structure of a memory transistor.

FIG. 3A is a diagram showing the memory cell including the memory transistor in a program state (write state).

FIG. 3B is a diagram showing the memory cell including the memory transistor in an erase state.

FIG. 4 is a graph showing relationships between a gate voltage and a drain current in the program state and the erase state.

FIG. 5 is a diagram showing a complementary cell.

FIG. 6 shows states (storage states) of data in the complementary cell and relationships between properties of a gate voltage Veg and properties of a drain current Id, the properties corresponding to the states of the data.

FIG. 7 is a schematic diagram showing a configuration of an IC chip including a memory circuit according to a comparative example.

FIG. 8 is a graph showing relationships between properties of a gate voltage Vg and properties of the drain current Id of a reference transistor and memory transistors.

FIG. 9 is a schematic diagram showing an IC chip including a memory circuit according to an embodiment of the present disclosure.

FIG. 10 is a graph showing a relationship between a threshold voltage and a frequency of the memory transistors in the erase state.

FIG. 11 is a graph showing relationships between the properties of the gate voltage Vg and the properties of the drain current Id of the reference transistor and the memory transistors.

### DESCRIPTION OF EMBODIMENTS

Now, an exemplified embodiment according to the present disclosure is described with reference to the drawings.

### 1. Complementary Cell

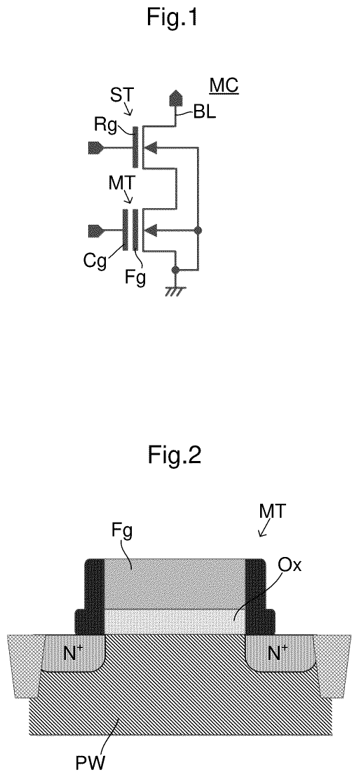

FIG. 1 is a diagram showing a configuration of a memory cell MC. The memory cell MC includes a memory transistor MT and a selection transistor ST. The memory transistor MT, which is constituted by an NMOS transistor (N-channel MOSFET (Metal-Oxide-Semiconductor Field-Effect Transistor)), is a device for storing data. The memory transistor MT includes a control gate Cg and a floating gate Fg.

The selection transistor ST, which is constituted by the NMOS transistor, is a device for selecting the memory transistor MT. A source of the memory transistor MT is connected to a node to which a ground potential is applied. A drain of the memory transistor MT is connected to a source of the selection transistor ST. A drain of the selection transistor ST is connected to a bit line BL. The selection transistor ST includes a read gate Rg. The selection transistor ST is turned ON/OFF in accordance with voltage that is applied to the read gate Rg.

FIG. 2 is a view illustrating a vertical structure of the memory transistor MT. As illustrated in FIG. 2, a P-well region PW is formed in a semiconductor substrate. Two N+ regions are formed in a surface of the P-well region PW. An oxide film Ox is formed directly on a channel region that is sandwiched between the two N+ regions. The floating gate Fg is formed directly on the oxide film Ox. The control gate Cg (not shown) is arranged directly on the floating gate Fg.

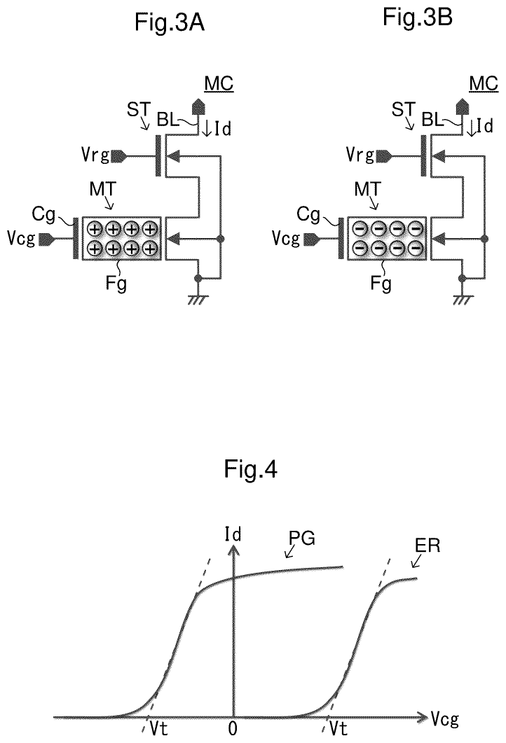

FIG. 3A is a diagram showing the memory cell MC including the memory transistor MT in a program state (write state). By application of a high-negative voltage as the gate voltage Veg to the control gate Cg, as shown in FIG. 3A, electrons are extracted from the floating gate Fg to bring the floating gate Fg into a hole-rich state. This state is the program state.

Meanwhile, FIG. 3B is a diagram showing the memory cell MC including the memory transistor MT in an erase state. By application of a high-positive voltage as the gate voltage Veg to the control gate Cg, as shown in FIG. 3B, electrons are injected into the floating gate Fg to bring the floating gate Fg into an electron-rich state. This state is the erase state.

FIG. 4 is a graph showing relationships between the gate voltage Vcg that is applied to the control gate Cg of the memory transistor MT and a drain current Id that flows through the memory transistor MT, the memory transistor MT being in a program state PG and an erase state ER with the selection transistor ST turned ON by a gate voltage Vrg that is applied to the read gate Rg. As shown in FIG. 4, a threshold voltage Vt has a negative value in the program state PG, and the threshold voltage Vt has a positive value in the erase state ER.

Such properties of the program state and the erase state cause the drain current Id to be high and low in the program state and the erase state by the application of the gate voltage Vcg for reading to the control gate Cg. Thus, by the application of the gate voltage Veg for reading to the control gate Cg with the selection transistor ST turned ON, the drain Id flows through the bit line BL, and data can be read on the basis of whether the drain current Id is high or low.

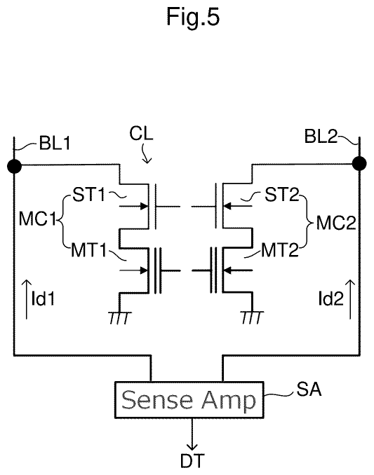

In the embodiment according to the present disclosure, as shown in FIG. 5, two memory cells are arrayed to constitute what is called a complementary memory cell (complementary cell). This complementary cell CL includes a first memory cell MC1 and a second memory cell MC2. The first memory cell MC1 includes a first selection transistor ST1 and a first memory transistor MT1. The second memory cell MC2 includes a second selection transistor ST2 and a second memory transistor MT2. A first bit line BL1 is connected to the first selection transistor ST1. A second bit line BL2 is connected to the second selection transistor ST2. The bit lines BL1 and BL2 are connected to a sense amplifier SA. The sense amplifier SA reads data DT of one bit by detecting a magnitude relationship between a first drain current Id1 that flows through the first memory cell MC1 and a second drain current Id2 that flows through the second memory cell MC2 with the selection transistors ST1 and ST2 turned ON and with gate voltages for reading applied to control gates of the memory cells MT1 and MT2.

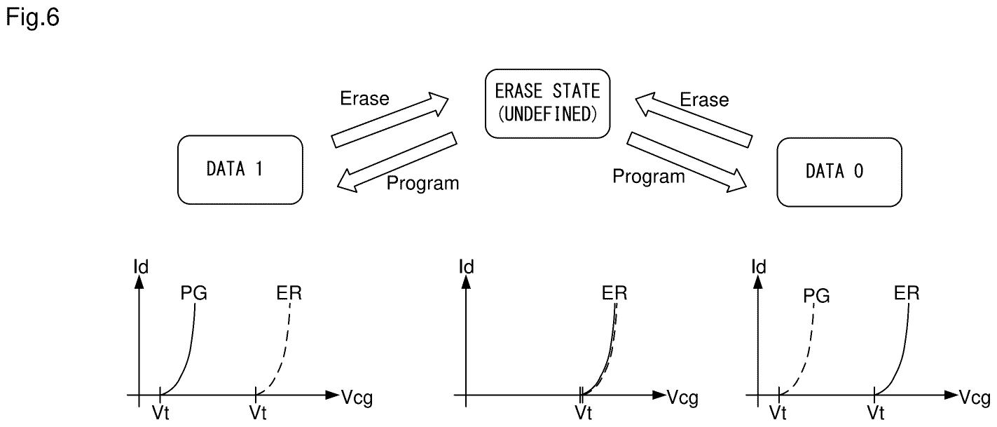

FIG. 6 shows states (storage states) of data in the complementary cell CL and relationships between properties of the gate voltage Veg and properties of the drain current Id, the properties corresponding to the states of the data. Note that, in FIG. 6, solid lines represent properties of the first memory transistor MT1, and dashed lines represent properties of the second memory transistor MT2.

As shown in FIG. 6, while the memory transistors MT1 and MT2 have been in the erase state ER, the data DT that is read by the sense amplifier SA is undefined, and the complementary cell CL is in the erase state.

While the first memory transistor MT1 has been in the program state, and the second memory transistor MT2 has been in the erase state ER, the first drain current Id1 is higher than the second drain current Id2. Thus, the data DT is read as “1” by the sense amplifier SA. In other words, data “1” is stored in the complementary cell CL.

While the second memory transistor MT2 has been in the program state, and the first memory transistor MT1 has been in the erase state ER, the first drain current Id1 is lower than the second drain current Id2. Thus, the data DT is read as “0” by the sense amplifier SA. In other words, data “0” is stored in the complementary cell CL.

As shown in FIG. 6, depending on which of the memory transistors MT1 and MT2 is switched from the erase state into the program state, the data “1” or “0” is stored in the complementary cell CL. While the data “1” or “0” has been stored, by switching either one in the program state among the memory transistors into the erase state, the complementary cell CL is brought into the erase state.

### 2. Comparative Example

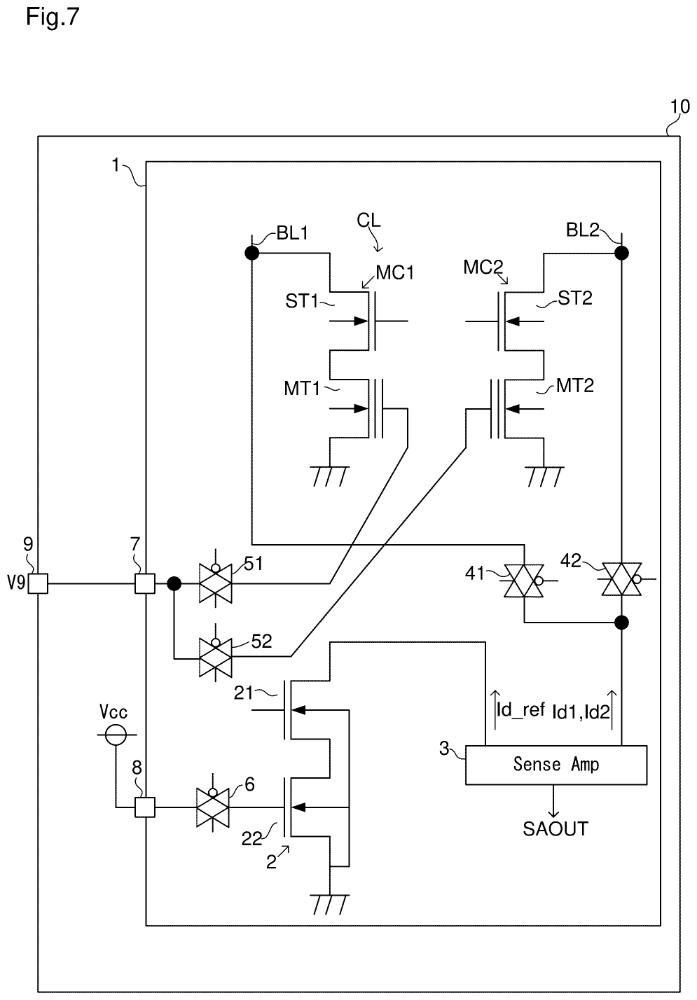

Now, a function to check whether the erase state as described above has been established in the complementary cell CL (erase-state check function) is described. In the description of this function, first, a comparative example to be compared with the embodiment according to the present disclosure is described. FIG. 7 is a schematic diagram showing a configuration of an IC (Integrated Circuit) chip 10 including a memory circuit 1 according to the comparative example.

The memory circuit 1 corresponds to a memory function block (memory IP (Intellectual Property core) in the IC chip 10. The memory circuit 1 includes the complementary cell CL, a reference cell 2, a sense amplifier 3, switches 41 and 42, switches 51 and 52, and a switch 6. The memory circuit 1 includes terminals 7 and 8 for establishing electrical connection to an outside of the circuit.

Circuits other than the memory circuit 1 in the IC chip 10, which are not shown in FIG. 7, may be arbitrarily configured. The IC chip 10 includes an external terminal 9 for establishing electrical connection to an outside of the chip.

Similar to the above-described configuration, the complementary cell CL includes the first memory cell MC1 and the second memory cell MC2. The first memory cell MC1 includes the first selection transistor ST1 and the first memory transistor MT1. The second memory cell MC2 includes the second selection transistor ST2 and the second memory transistor MT2. The complementary cell CL is capable of storing the data “1” or “0.” Note that, in FIG. 7, only the complementary cell CL corresponding to one bit among a plurality of complementary cells CL that are actually arranged as a memory-cell array in the memory circuit 1 is shown.

The first bit line BL1 that is connected to the first selection transistor ST1 is connected to a first end of the switch 41. The second bit line BL2 that is connected to the second selection transistor ST2 is connected to a first end of the switch 42. Second ends of the switches 41 and 42 are connected commonly to a first input end of the sense amplifier 3. Which of the switches 41 and 42 is turned ON/OFF is complimentarily controlled at a time when the erase-state check function is implemented. Specifically, the switch 42 is turned OFF while the switch 41 has been turned ON, and the switch 42 is turned ON while the switch 41 has been turned OFF.

The control gate of the first memory transistor MT1 is connected to a first end of the switch 51. The control gate of the second memory transistor MT2 is connected to a first end of the switch 52. Second ends of the switches 51 and 52 are connected commonly to the terminal 7. Which of the switches 51 and 52 is turned ON/OFF is complimentarily controlled at the time when the erase-state check function is implemented. Specifically, the switch 52 is turned OFF while the switch 51 has been turned ON, and the switch 52 is turned ON while the switch 51 has been turned OFF.

The terminal 7 is connected to the external terminal 9. The external terminal 9 is a terminal for applying a variable external voltage V9. While the switch 51 has been turned ON (switch 52 has been turned OFF), the external voltage V9 can be applied to the control gate of the first memory transistor MT1. While the switch 52 has been turned ON (switch 51 has been turned OFF), the external voltage V9 can be applied to the control gate of the second memory transistor MT2.

The reference cell 2 includes a reference selection switch 21 and a reference transistor 22. The reference selection switch 21 and the reference transistor 22 are each the NMOS transistor. A drain of the reference selection switch 21 is connected to a second input end of the sense amplifier 3. A source of the reference selection switch 21 is connected to a drain of the reference transistor 22. A source of the reference transistor 22 is connected to a node to which the ground potential is applied.

A gate of the reference transistor 22 is connected to a first end of the switch 6. A second end of the switch 6 is connected to the terminal 8. A power-supply voltage Vcc can be applied to the terminal 8. While the reference selection switch 21 has been turned ON and the switch 6 has been turned ON, by the application of the power-supply voltage Vcc to the gate of the reference transistor 22, a reference drain current Id_ref in accordance with properties of the reference transistor 22 flows through the reference cell 2.

The sense amplifier 3 detects a magnitude relationship between the first drain current Id1 that flows through the first memory cell MC1 via the switch 41 or the second drain current Id2 that flows through the second memory cell MC2 via the switch 42 and the reference drain current Id_ref, and then outputs results of the detection as amplifier output SAOUT. Note that, another sense amplifier (not shown) for reading the data from the complementary cell CL is provided in addition to the sense amplifier 3 in the memory circuit 1.

Next, operation of the erase-state check function by the memory circuit 1 configured as described above is described. In order to check whether the complementary cell CL has been in the erase state, it is necessary to check whether both the memory cells MC1 and MC2 have been in the erase state. In the memory circuit 1, whether the memory cells MC1 and MC2 have been in the erase state is independently checked.

At a time of checking whether the first memory cell MC1 has been in the erase state, the switches 41 and 51 are turned ON (switches 42 and 52 are turned OFF), and the switch 6 is turned ON.

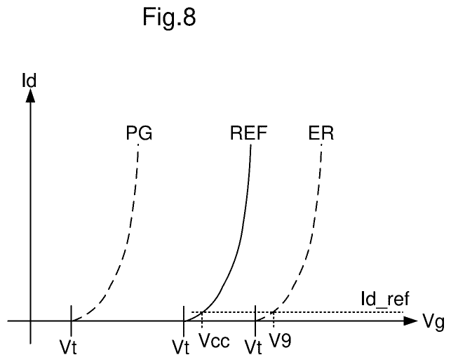

In this context, FIG. 8 shows relationships between properties of a gate voltage Vg and properties of the drain current Id of the reference transistor 22 and the memory transistors MT1 and MT2. In FIG. 8, properties of the reference transistor 22 are represented as reference properties REF, and properties in the erase state ER and properties in the program state PG of the memory transistors MT1 and MT2 are represented. The threshold voltage Vt of the reference properties REF has a value between the threshold voltage Vt in the program state PG and the threshold voltage Vt in the erase state ER.

By the application of the power-supply voltage Vcc to the gate of the reference transistor 22, the reference drain current Id_ref in accordance with the reference properties REF as shown in FIG. 8 flows through the reference cell 2. Meanwhile, the external voltage V9 is applied while increased from its default value to the external terminal 9. This default value is a value between the power-supply voltage Vcc and the threshold voltage Vt in the erase state ER.

First, the external voltage V9 at the initial value is applied to the external terminal 9. At this time, if the memory transistor MT1 has been in the erase state ER, the first drain current Id1 that flows through the first memory cell MC1 is zero. Thus, the sense amplifier 3 detects that the reference drain current Id_ref is higher than the first drain current Id1, and outputs the amplifier output SAOUT. In this case, the sense amplifier 3 detects the magnitude relationship between the drain currents with the external voltage V9 gradually increased from the default value. Then, if the magnitude relationship between the drain currents, the relationship being detected by the sense amplifier 3, is inverted (that is, Id_ref<Id1) at a certain value of the external voltage V9, the threshold voltage Vt in the erase state ER is specified in response to the external voltage V9 at this time. The magnitude relationship between the drain currents is inverted at the external voltage V9 shown in FIG. 8.

In such a way, in this comparative example, by the application of the variable external voltage V9, it is possible to detect that the first memory transistor MT1 has been in the erase state ER, and to detect the threshold voltage Vt in the erase state ER. With this, the threshold voltage Vt in accordance with variation in the properties of the first memory transistor MT1 can be detected. Note that, if the sense amplifier 3 detects Id1>Id_ref by the application of the external voltage V9 at the default value, it is detected that the first memory transistor MT1 has been in the program state PG.

Meanwhile, at a time of checking whether the second memory cell MC2 has been in the erase state, the switches 42 and 52 are turned ON (switches 41 and 51 are turned OFF), and the switch 6 is turned ON. As in the above description, while the external voltage V9 is increased from the default value, the sense amplifier 3 detects the magnitude relationship between the reference drain current Id_ref and the second drain current Id2. With this, whether the second memory transistor MT2 has been in the erase state or in the program state, and the threshold voltage Vt in the erase state can be detected. If both the first memory cell MC1 and the second memory cell MC2 have been in the erase state, it is determined that the complementary cell CL is in the erase state.

However, in this comparative example, there are such problems that the operation of the erase-state check function is complicated, and that the external terminal 9 needs to be provided to the IC chip 10.

### 3. Embodiment According to Present Disclosure

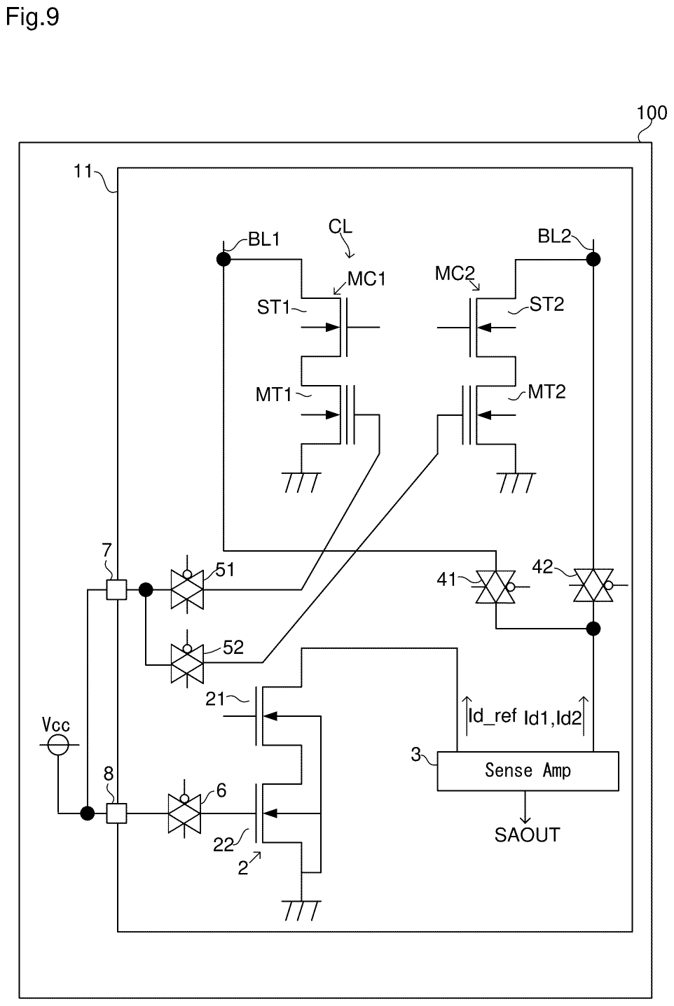

In order to solve the problems as described above of the comparative example, the embodiment according to the present disclosure is implemented as described below. FIG. 9 is a schematic diagram showing an IC chip 100 including a memory circuit 11 according to the embodiment of the present disclosure.

The memory circuit 11 is different from the memory circuit 1 (FIG. 7) according to the comparative example in that the terminals 7 and 8 are connected commonly to a node to which the power-supply voltage Vcc is applied. Thus, the IC chip 100 is not provided with the external terminal 9 that is provided to the IC chip 10 according to the comparative example.

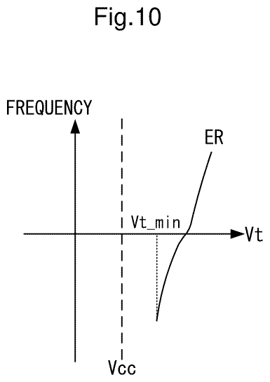

FIG. 10 shows a relationship between the threshold voltage Vt and a frequency of the memory transistors MT1 and MT2 in the erase state ER. Note that, the frequency has a maximum value at a point where the frequency intersects with the axis representing the threshold voltage Vt. As shown in FIG. 10, the power-supply voltage Vcc is smaller than a minimum value Vt_min of the threshold voltage Vt in the erase state ER. In other words, the threshold voltage Vt in the erase state ER is secured to be equal to or higher than the power-supply voltage Vcc.

In this context, operation of the erase-state check function by the memory circuit 11 is described. In order to check whether the complementary cell CL has been in the erase state, it is necessary to check whether both the memory cells MC1 and MC2 have been in the erase state. In the memory circuit 11, whether the memory cells MC1 and MC2 have been in the erase state is independently checked.

At a time of checking whether the first memory cell MC1 has been in the erase state, the switches 41 and 51 are turned ON (switches 42 and 52 are turned OFF), and the switch 6 is turned ON.

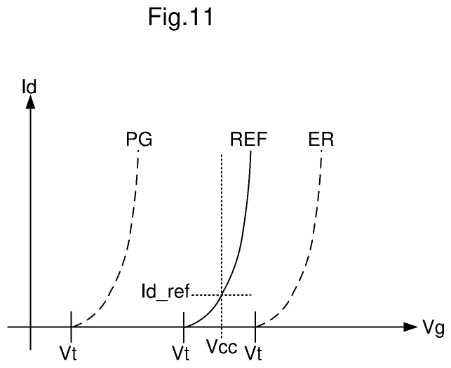

In this context, FIG. 11 shows relationships between the properties of the gate voltage Vg and the properties of the drain current Id of the reference transistor 22 and the memory transistors MT1 and MT2. In FIG. 11, the properties of the reference transistor 22 are represented as the reference properties REF, and the properties in the erase state ER and the properties in the program state PG of the memory transistors MT1 and MT2 are represented. The threshold voltage Vt of the reference properties REF has the value between the threshold voltage Vt in the program state PG and the threshold voltage Vt in the erase state ER. In addition, the threshold voltage Vt of the reference properties REF is lower than the power-supply voltage Vcc.

By the application of the power-supply voltage Vcc to the gate of the reference transistor 22, the reference drain current Id_ref in accordance with the reference properties REF as shown in FIG. 11 flows through the reference cell 2. Meanwhile, by application of the power-supply voltage Vcc to the terminal 7, the power-supply voltage Vcc is applied to the control gate of the first memory transistor MT1. The power-supply voltage Vcc is lower than the threshold voltage Vt in the erase state ER. Thus, if the first memory transistor MT has been in the erase state ER, the first drain current Id1 that flows through the first memory cell MC1 is zero. As a result, the sense amplifier 3 detects Id1<Id_ref. In this way, it is detected that the first memory transistor MT1 has been in the erase state ER. As shown in FIG. 10 referred to above, even when the threshold voltage Vt in the erase state ER varies, the power-supply voltage Vcc is lower than the threshold voltage Vt. Thus, it is possible to detect that the first memory transistor MT1 has been in the erase state. Meanwhile, if the first memory transistor MT1 has been in the program state PG, the sense amplifier 3 detects Id1>Id_ref. In this way, it is detected that the first memory transistor MT1 has been in the program state PG.

In such a way, according to this embodiment, by the application of the power-supply voltage Vcc to the terminals 7 and 8, whether the first memory cell MC1 has been in the erase state or in the program state can be detected. Meanwhile, at a time of checking whether the second memory cell MC2 has been in the erase state, the switches 42 and 52 are turned ON (switches 41 and 51 are turned OFF), and the switch 6 is turned ON. As in the above description, the sense amplifier 3 detects the magnitude relationship between the reference drain current Id_ref and the second drain current Id2.

In such a way, according to this embodiment, the erase-state check function is implemented by the application of the power-supply voltage Vcc to the terminal 7. Thus, the operation of the erase-state check function can be simplified, and the external terminal 9 similar to that according to the comparative example need not be provided to the IC chip 100. Note that, the terminals 7 and 8 need not necessarily be independent terminals as in the configuration shown in FIG. 9 according to this embodiment, and may be a common terminal to which the power-supply voltage Vcc can be applied. However, the independent terminals are more advantageous in that the configuration of the memory circuit 1 according to the comparative example also can be used.

### 4. Others

Note that, various technical features according to the present disclosure may be implemented as in the embodiment described hereinabove, or may be variously modified within the gist of the technical creation. In other words, all the features of the embodiment described hereinabove are merely examples, and hence should not be regarded as limitations. In addition, it should be understood that the technical scope of the present invention is not limited to the embodiment described hereinabove, and encompasses meaning of equivalents of the elements described in the scope of claims and all modifications within the scope of claims.

### 5. Appendices

As described hereinabove, a memory circuit (11) according to an aspect of the present disclosure is, for example, a memory circuit that is provided to an IC chip (100), the memory circuit (11) including:
a complementary cell (CL) which includes
   a first memory cell (MC1) that includes a first memory transistor (MT1), and
   a second memory cell (MC2) that includes a second memory transistor (MT2);
a reference cell (2) which includes a reference transistor (22);
a first terminal (7)
   which is connectable to
      a gate of the first memory transistor and
      a gate of the second memory transistor, and
   to which a first power-supply voltage (Vcc) can be applied;
a second terminal (8)
   which is connectable to a gate of the reference transistor, and
   to which a second power-supply voltage (Vcc) can be applied; and
a detection unit (3) which detects a magnitude relationship between
   current that flows through
      the first memory cell or
      the second memory cell, and
   current that flows through the reference cell (a first configuration).

Further, in the first configuration, the first power-supply voltage and the second power-supply voltage may be the same power-supply voltage (a second configuration).

Still further, in the second configuration, the first terminal and the second terminal may be independent terminals (a third configuration).

Yet further, in any of the first to the third configurations, the reference cell (2) may include a reference selection transistor (21) which is connected to the reference transistor (22) (a fourth configuration).

Yet further, in any of the first to the fourth configurations, the memory circuit (11) may further include first switches (51 and 52) which are arranged between the gate of the first memory transistor (MT1) and the gate of the second memory transistor (MT2) and the first terminal (7) (a fifth configuration).

Yet further, in any of the first to the fifth configurations, the memory circuit (11) may further include a second switch (6) which is arranged between the gate of the reference transistor (22) and the second terminal (8) (a sixth configuration).

Yet further, in any of the first to the sixth configurations, the memory circuit (11) may further include:
a third switch (41) having a first end which is connected to a first bit line (BL1) to be connected to the first memory cell (MC1); and
a fourth switch (42) having a first end which is connected to a second bit line (BL2) to be connected to the second memory cell (MC2), and a second end of the third switch and a second end of the fourth switch are connected commonly to an input end of the detection unit (3) (a seventh configuration).

Yet further, the IC chip (100) according to the aspect of the present disclosure includes the memory circuit (11) having any of the configurations.

### INDUSTRIAL APPLICABILITY

The present disclosure is applicable to memory circuits for various purposes.

### REFERENCE SIGNS LIST

1 memory circuit
2 reference cell
3 sense amplifier
6 switch
7,8 terminal
9 external terminal
10 IC chip
11 memory circuit
21 reference selection switch
22 reference transistor
41, 42 switch
51,52 switch
100 IC chip
BL bit line
BL1 first bit line
BL2 second bit line
CL complementary cell
Cg control gate
Fg floating gate
MC memory cell
MC1 first memory cell
MC2 second memory cell
MT memory transistor
MT1 first memory transistor
MT2 second memory transistor
Ox oxide film
PW P-well region
Rg read gate
SA sense amplifier
ST selection transistor
ST1 first selection transistor
ST2 second selection transistor

1. A memory circuit that is provided to an IC chip, the memory circuit comprising:
a complementary cell which includes
a first memory cell that includes a first memory transistor, and
a second memory cell that includes a second memory transistor;
a reference cell which includes a reference transistor;
a first terminal
which is connectable to
a gate of the first memory transistor and
a gate of the second memory transistor, and
to which a first power-supply voltage can be applied;
a second terminal
which is connectable to a gate of the reference transistor, and
to which a second power-supply voltage can be applied; and
a detection unit which detects a magnitude relationship between
current that flows through
the first memory cell or
the second memory cell, and
current that flows through the reference cell.

2. The memory circuit according to claim 1, wherein the first power-supply voltage and the second power-supply voltage is a same power-supply voltage.

3. The memory circuit according to claim 2, wherein the first terminal and the second terminal are independent terminals.

4. The memory circuit according to claim 1, wherein the reference cell includes a reference selection transistor which is connected to the reference transistor.

5. The memory circuit according to claim 1, further comprising first switches which are arranged between the gate of the first memory transistor and the gate of the second memory transistor and the first terminal.

6. The memory circuit according to claim 1, further comprising a second switch which is arranged between the gate of the reference transistor and the second terminal.

7. The memory circuit according to claim 1, further comprising:
a third switch having a first end which is connected to a first bit line to be connected to the first memory cell; and
a fourth switch having a first end which is connected to a second bit line to be connected to the second memory cell, wherein
a second end of the third switch and a second end of the fourth switch are connected commonly to an input end of the detection unit.

8. An IC chip, comprising the memory circuit according to claim 1.
